(19) United States
(12) Patent Application Publication
(10) Pub. No.: US 2014/0102763 A1
(43) Pub. Date: Apr. 17, 2014

(54) RIGID FLEXIBLE CIRCUIT BOARD WITH IMPEDANCE CONTROL

(71) Applicant: ADVANCED FLEXIBLE CIRCUITS CO., LTD., TAOYUAN COUNTY (TW)

(72) Inventor: GWUN-JIN LIN, TAOYUAN COUNTY (TW)

(73) Assignee: ADVANCED FLEXIBLE CIRCUITS CO., LTD., TAOYUAN COUNTY (TW)

(21) Appl. No.: 14/039,068

(22) Filed: Sep. 27, 2013

(30) Foreign Application Priority Data
Oct. 16, 2012 (TW) 101138042

(51) Int. Cl. H05K 1/02

(52) U.S. Cl. CPC H05K 1/0237
USPC 174/250

(57) ABSTRACT

A rigid-flexible circuit board includes at least one flexible circuit board and at least one rigid circuit board. The flexible circuit board includes a flexible-board substrate, a plurality of flexible circuit board differential mode signal lines, at least one flexible circuit board grounding line, a flexible circuit board insulation layer formed on the upper surface of the flexible-board substrate and covering the flexible circuit board differential mode signal lines and the flexible circuit board grounding line. The rigid circuit board is stacked on the stacking section of the flexible circuit board. A shielding layer is formed on the flexible circuit board insulation layer of the flexible circuit board and corresponds to the extension section of the flexible circuit board. The shielding layer further extends from the extension section to the stacking section. An impedance control structure is formed on the shielding layer to control the impedance of the flexible circuit board differential mode signal lines.

### BACKGROUND OF THE INVENTION

1. Field of the Invention

The present invention relates to a rigid-flexible circuit board, and in particular to a rigid-flexible circuit board including an impedance control structure.

2. The Related Arts

The vigorous progress of electronic industry makes printed circuit boards playing an important role in taking the place of the conventional ways of arranging flat cables. Further, the development of a flexible printed circuit (FPC) brings a significant upgrade of the electronic industry. The FPC is a technique that a flexible copper foil based substrate is subjected to processing to have wiring directly laid on the substrate. The industry is now continuously devoting themselves to researches and developments of circuit capacity that can be adopted for miniaturization, weight reduction, and dense integration of electronic components of electronic and electrical appliances by increasing the layers of a printed circuit board to form a multilayer printed circuit board for greatly expanding the area for wire laying. Various devices, such as mobile phones, notebook computers, and satellite navigation systems, have already adopted the technology of multilayer circuit board.

The printed circuit boards and the flexible printed circuit boards each have their own advantages and characteristics and different types of circuit boards are generally used in different applications. Due to the increasingly emergence of new and diversified electronic products in the market, the conventionally used simple printed circuit boards or flexible printed circuit boards are generally incapable to satisfy the emerging needs. Thus, a compound circuit board or a rigid-flexible circuit board is available for such needs.

### SUMMARY OF THE INVENTION

In the field of electronic technology, a rigid-flexible circuit board has been commonly used in various electronic devices. However, the electronic devices that are currently available are made to transmit signals that are generally high frequency signals. The manufacturers generally overlook the significance of impedance control in the transmission of high frequency signals and this often results in failure transmission and distortion of signals. Particularly, when a flexible circuit board is applied to transmission through differential mode signal lines, due to the material characteristics of the flexible circuit board being flexible and bendable, the transmission of differential mode signal is readily subjected to troubles caused by factors including surrounding environment, the wires themselves, and poor impedance control.

Thus, an object of the present invention is to provide an impedance control structure included rigid-flexible circuit board, wherein impedance of differential mode signal line is properly controlled with the impedance control structure.

The technical solution adopted in the present invention to address the technical problems of the prior art is that in a circuit board structure that comprises at least one flexible circuit board and at least one rigid circuit board and a shielding layer is formed on a flexible circuit board insulation layer of the flexible circuit board and corresponds to an extension section of the flexible circuit board. An impedance control structure is formed on the shielding layer to control the impedance of flexible circuit board differential mode signal lines. The shielding layer has at least one portion covering and electrically connecting with an extended section of a grounding section of rigid circuit board.

In another embodiment of the present invention, a shielding layer is formed on the flexible circuit board insulation layer of the flexible circuit board and corresponds to the stacking section and the extension section of the flexible circuit board. An impedance control structure is formed on the shielding layer of the flexible circuit board and corresponds to the flexible circuit board differential mode signal lines of the flexible boar. The impedance control structure controls the impedance of the flexible circuit board differential mode signal lines.

The present invention can be embodied as a single-sided board or a double-sided board. In the structure of a double-sided board, the lower surface of the flexible circuit board is provided with a corresponding rigid circuit board structure at a location corresponding to the stacking section, or alternatively, left and right ends of the flexible circuit board are respectively provided with corresponding rigid circuit board structures.

With the technical solution adopted in the present invention, an impedance control structure is formed on a flexible circuit board of a rigid-flexible circuit board so that the impedance control structure controls the impedance that differential mode signals are transmitted through the flexible circuit board. In this way, errors and distortions of signal transmission can be eliminated in the transmission of high frequency differential mode signals of an electronic device.

### BRIEF DESCRIPTION OF THE DRAWINGS

The present invention will be apparent to those skilled in the art by reading the following description of preferred embodiments of the present invention, with reference to the attached drawings, in which:

FIG. 1 is a top plan view of a first embodiment of the present invention;

FIG. 2 is a cross-sectional view of the embodiment of FIG. 1 taken along line 2-2;

FIG. 3 is a cross-sectional view taken along lines 3-3 of FIG. 1;

FIG. 4 is a cross-sectional view taken along lines 4-4 of FIG. 1;

FIG. 5 is a perspective view showing a plurality of cluster lines of FIG. 1 bundled by a bundling member after being subjected to side portion folding and bundling;

FIG. 6 is a cross-sectional view of a bundled structure formed by using the bundling member to loop together the cluster lines of a flexible circuit board;

FIG. 7 is a cross-sectional view showing a second embodiment according to the present invention;

FIG. 8 is a cross-sectional view showing a third embodiment according to the present invention;

FIG. 9 is a cross-sectional view showing a fourth embodiment according to the present invention;

FIG. 10 is a cross-sectional view showing a fifth embodiment according to the present invention;

FIG. 11 is a cross-sectional view showing a sixth embodiment according to the present invention;

FIG. 12 is a cross-sectional view showing a seventh embodiment according to the present invention;

FIG. 13 is a cross-sectional view showing an eighth embodiment according to the present invention;

FIG. 14 is a cross-sectional view showing a ninth embodiment according to the present invention; and

FIG. 15 is a cross-sectional view showing a tenth embodiment according to the present invention.

### DETAILED DESCRIPTION OF THE PREFERRED EMBODIMENTS

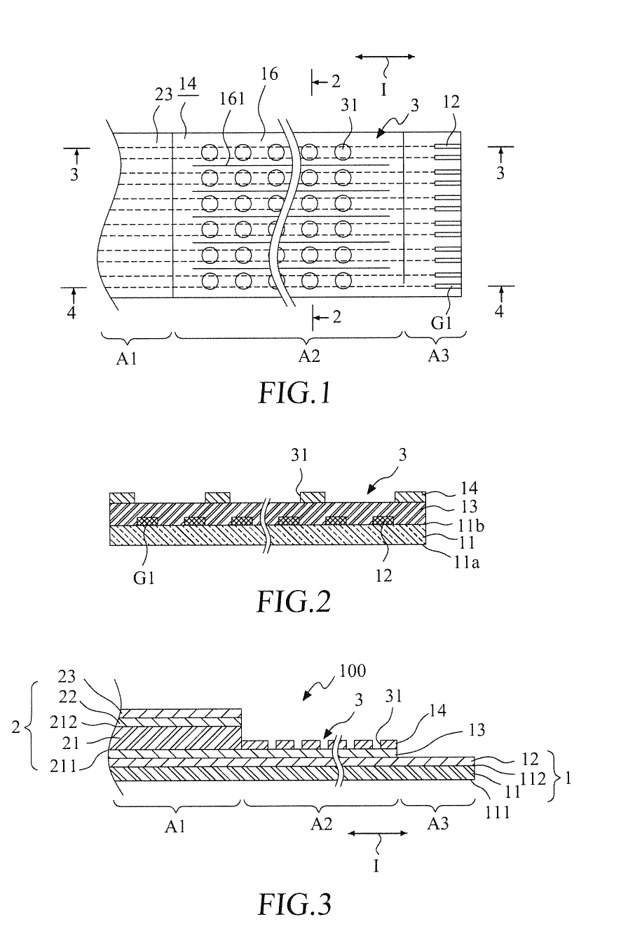

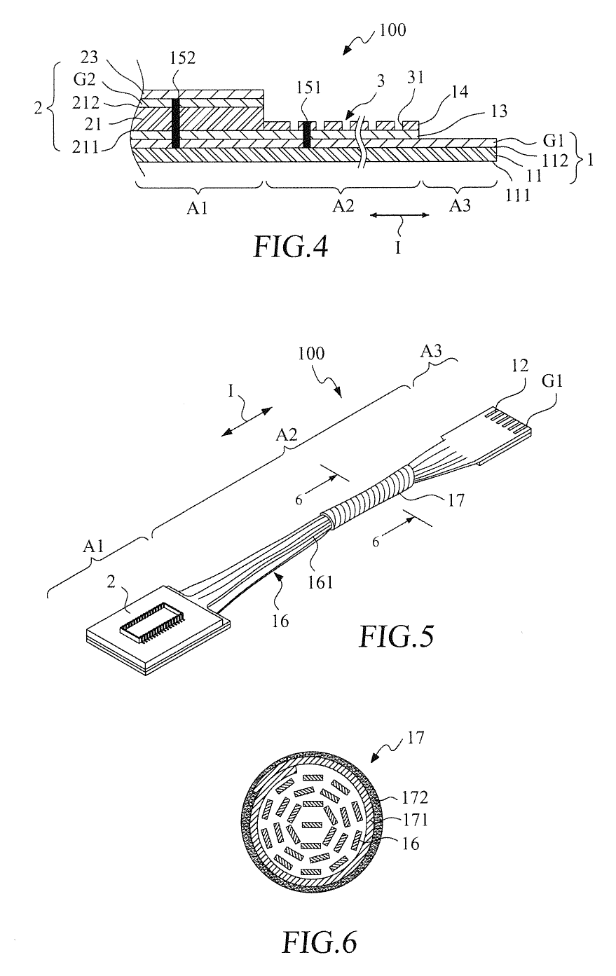

Referring to FIGS. 1-4, FIG. 1 is a top plan view of a first embodiment of the present invention; FIG. 2 is a cross-sectional view of the embodiment of FIG. 1 taken along line 2-2; FIG. 3 is a cross-sectional view taken along lines 3-3 of FIG. 1; and FIG. 4 is a cross-sectional view taken along lines 4-4 of FIG. 1. An impedance control structure included rigid-flexible circuit board according to the present invention, generally designated at 100, comprises a flexible circuit board 1 and a first rigid circuit board 2. The flexible circuit board 1 comprises a flexible-board substrate 11 that extends in an extension direction I and comprises a lower surface 111 and an upper surface 112. The flexible circuit board 1 defines a stacking section A1, an extension section A2, and an exposed conduction section A3 along the extension direction I. The first rigid circuit board 2 corresponds to and is stacked on the stacking section A1. The extension section A2 extends outside an outer end of the stacking section A1 and the exposed conduction section A3 extends outside an outer end of the extension section A2.

A plurality of parallel first flexible-board differential mode signal lines 12 is formed on the upper surface 112 of the flexible-board substrate 11 in the extension direction I to extend from the stacking section A1 to the extension section A2 and the exposed conduction section A3. Also referring to FIG. 2, the first flexible-board differential mode signal lines 12 comprise a predetermined gas formed between adjacent ones and every two of the first flexible-board differential mode signal lines 12 are paired for transmission of differential mode signals.

Besides a plurality of first flexible-board differential mode signal lines 12, the upper surface 112 of the flexible-board substrate 11 also comprises at least one first flexible-board grounding line G1 formed thereon.

A first flexible-board insulation layer 13 is formed on the upper surface 112 of the flexible-board substrate 11 and covers the portions of the first flexible-board differential mode signal lines 12 and the first flexible-board grounding line G1 that are located in the stacking section A1 and the extension section A2 but does not cover the surface of the exposed conduction section A3 so that the exposed conduction section A3 constitutes a conventional golden-finger insertion structure.

A first shielding layer 14 is formed on a surface of the first flexible-board insulation layer 13 of the flexible circuit board 1 and corresponds to the extension section A2. The first shielding layer 14 is electrically connected through at least one first via hole 151 to the first flexible-board grounding line G1 (see FIG. 4).

The first shielding layer 143 can be formed on the surface of the first flexible-board insulation layer 13 through for example printing and screen printing of a conductive substance, such as copper paste and silver paste. The first shielding layer 143 can be alternatively mounted on the surface of the first flexible-board insulation layer 13 by laminating or bonding a conductive foil, such as a copper foil, a silver foil, and an aluminum foil.

The first shielding layer 14 comprises a first impedance control structure 3 arranged in the extension section A2. The first impedance control structure 3 is arranged to correspond to the first flexible-board differential mode signal lines 12 of the flexible circuit board 1 and the first impedance control structure 3 serves as an impedance control structure for the first flexible-board differential mode signal lines 12. In a practical application, the first impedance control structure 3 is composed of a plurality of openings 31 formed in the first shielding layer 14. The openings 31 can be of various geometric configurations, such as circular holes, rhombus, and rectangle.

The first rigid circuit board 2 comprises a first rigid-board substrate 21. The first rigid-board substrate 21 has a lower surface 211 stacked on a top surface of the first flexible-board insulation layer 13 of the flexible circuit board 1 to correspond to the stacking section A1. The upper surface 212 of the first rigid-board substrate 21 comprises a plurality of first rigid-board differential mode signal lines 22 formed thereon and a first rigid-board insulation layer 23 is set to cover the first rigid-board differential mode signal lines 22. At least one of the first rigid-board differential mode signal lines 22 is electrically connected through a conventional via hole (not shown) to at least a corresponding one of the first flexible-board differential mode signal lines 12.

As shown in FIG. 4, besides the first rigid-board differential mode signal lines 22, the upper surface 212 of the first rigid-board substrate 21 comprises at least one first rigid-board grounding line G2 formed thereon and connected through at least one second via hole 152 to the first flexible-board grounding line G1 of the flexible circuit board 1.

The first flexible-board grounding line G1 and the first flexible-board differential mode signal lines 12 are formed on the upper surface 112 of the flexible-board substrate 11 in a coplanar manner so that a compound reference character G1(12) is used in the drawings to indicate the first flexible-board grounding line G1 and the first flexible-board differential mode signal lines 12, individually or collectively. Similarly, the first rigid-board grounding line G2 and the first rigid-board differential mode signal lines 22 are formed on the upper surface 212 of the first rigid-board substrate 21 in a coplanar manner so that a compound reference character G2(22) is used in the drawings to indicate the first rigid-board grounding line G2 and the first rigid-board differential mode signal lines 22, individually or collectively 2.

Also referring to FIGS. 1 and 5, FIG. 5 is a perspective view showing a plurality of cluster lines of FIG. 1 bundled by a bundling member after being subjected to side portion folding and bundling. The flexible circuit board 1 comprises a plurality of slit lines 161 that is formed by slitting in the extension direction I to be each located between two adjacent pairs of the first flexible-board differential mode signal lines 12 so as to form a plurality of cluster line 16. As such, the flexible circuit board 1 is allowed to make use of the slit lines 161 for folding back side portions of the extension section A2 of the flexible circuit board 1 to provide a width-reduced structure bundled by a bundling member 17 to form a clustered structure that helps extend through for example a bore of a conventional hinge.

Referring to FIG. 6, the bundling member 17 is of a spiral structure that warps around the cluster line 16 to form a bundled structure. The bundling member 17 is preferably formed in an integrated form to show a predetermined wrapping span, a predetermined helical angle, and a predetermined wrapping diameter for wrapping around the cluster lines 16 in a given wrapping direction. The bundling member 17 can be made of a shielding material or alternatively comprises a shielding layer 172 formed on an outer circumferential surface of a wrapping layer 171 made of a non-shielding material so as to provide an improved shielding effect.

In a practical application, the extension section of the flexible circuit board can be made in the form of one of an insertion plug, an insertion receptacle, a connector, a soldering terminal, an electronic component, and a surface-mounted component and the first rigid circuit board may receive one of an insertion receptacle, a connector, a soldering terminal, an electronic component, a surface-mounted component to couple thereto.

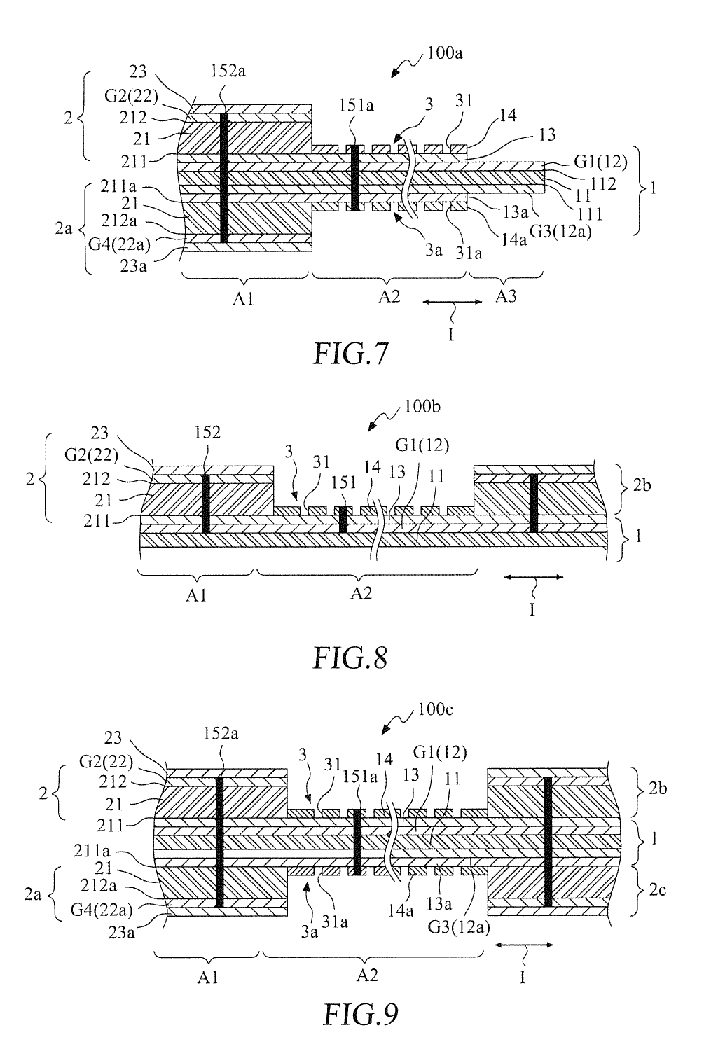

The first embodiment described above realizes the present invention in the form of a single-sided board. The present invention can be alternatively realized in the form of a double-sided board. As shown in FIG. 7, which is a cross-sectional view showing a second embodiment according to the present invention, an impedance control structure included rigid-flexible circuit board 100a according to the instant embodiment is an expanded structure formed by modifying the first embodiment shown in FIG. 4, wherein the upper surface 112 of the flexible-board substrate 11 of the flexible circuit board 1 similarly comprises the first flexible-board differential mode signal lines 12, the first flexible-board insulation layer 13, the first shielding layer 14, the first flexible-board grounding line G1, the first impedance control structure 3, the openings 31, the first rigid-board substrate 21, the first rigid-board differential mode signal line 22, the first rigid-board grounding line G2, and the first rigid-board insulation layer 23.

A similar corresponding structure is further provided on the lower surface 111 of the flexible-board substrate 11 of the flexible circuit board 1 and comprises second flexible-board differential mode signal lines 12a, a second flexible-board grounding line G3, a second flexible-board insulation layer 13a, a second shielding layer 14a, a second impedance control structure 3a, and openings 31a.

The second flexible-board differential mode signal line 12a are formed on the lower surface 111 of the flexible-board substrate 11 to extend in the extension direction I and correspond to the extension section A2. The second flexible-board grounding line G3 is also formed on the lower surface 111 of the flexible-board substrate 11 to extend in the extension direction I. The second flexible-board insulation layer 13a is formed on the lower surface 111 of the flexible-board substrate 11 to cover the second flexible-board differential mode signal lines 12a and the second flexible-board grounding line G3. The second shielding layer 14a is formed below the second flexible-board insulation layer 13a and corresponds to the extension section A2. The second impedance control structure 3a is formed on the second shielding layer 14a and corresponds to the second flexible-board differential mode signal lines 12a, whereby the second impedance control structure 3a is used to control the impedance of the second flexible-board differential mode signal lines 12a.

On a lower surface of the second flexible-board insulation layer 13a, a second rigid circuit board 2a that corresponds to the first rigid circuit board 2 is formed to correspond to the stacking section A1. The second rigid circuit board 2a comprises a second rigid-board substrate 21a, which has an upper surface 211a stacked on a bottom of the second flexible-board insulation layer 13a of the flexible circuit board 1 and corresponding to the stacking section A1. A lower surface 212a of the second rigid-board substrate 21a comprises a plurality of second rigid-board differential mode signal lines 22a and at least one second rigid-board grounding line G4 formed thereon and a second rigid-board insulation layer 23a is set to cover the second rigid-board differential mode signal lines 22a. At least one of the second rigid-board differential mode signal lines 22a is electrically connected through a fourth via holes 152a to at least a corresponding one of the second flexible-board differential mode signal lines 12a.

In the forgoing structure, the first shielding layer 14, the first flexible-board grounding line G1, the second flexible-board grounding line G3, and the second shielding layer 14a are electrically connected to each other by at least one third via hole 151a. The first rigid-board grounding line G2 and the second rigid-board grounding line G4 are electrically connected to each other by a fourth via hole 152a. Thus, the first shielding layer 14, the first flexible-board grounding line G1, the first rigid-board grounding line G2, the second flexible-board grounding line G3, the second rigid-board grounding line G4, and the second shielding layer 14a are electrically connected to each other.

Similarly, the first flexible-board differential mode signal lines 12, the first rigid-board differential mode signal lines 22, the second flexible-board differential mode signal lines 12a, and the second rigid-board differential mode signal lines 22a can be electrically connected to each other by at least one similar via hole (not shown).

The above embodiments are described by setting an end of the flexible circuit board (namely, the exposed conduction section of the flexible circuit board) to function as a golden-finger inserting structure and the other end being coupled to the first rigid circuit board and alternatively, one end of the flexible circuit board can be coupled to the first rigid circuit board, while the other end is coupled to the second rigid circuit board. Referring to FIG. 8, which is a cross-sectional view showing a third embodiment according to the present invention, a rigid-flexible circuit board 100b according to the instant embodiment is an expanded structure formed by modifying the first embodiment shown in FIG. 4 and the difference is that the flexible circuit board 1 is coupled to a third rigid circuit board 2b at an end thereof opposite to the first rigid circuit board 2. The third rigid circuit board 2b has a structure identical to that of the first rigid circuit board 2. A first shielding layer 14 located between the first rigid circuit board 2 and the third rigid circuit board 2b forms a first impedance control structure 3 functioning for impedance control for the first flexible-board differential mode signal lines 12 of the flexible circuit board 1.

FIG. 9 is a cross-sectional view showing a fourth embodiment according to the present invention. The instant embodiment provides a rigid-flexible circuit board 100c that is an expanded structure formed by modifying the embodiment illustrated in FIG. 8 and comprises, in structure, a first rigid circuit board 2 mounted to the upper surface of the flexible circuit board 1 to correspond to the stacking section A1 and a second rigid circuit board 2a mounted to the lower surface. A third rigid circuit board 2b is mounted to the upper surface of the flexible circuit board 1 at a location (the right-hand side end) opposite to the first rigid circuit board 2 and a fourth rigid circuit board 2c is mounted to the lower surface to correspond to the third rigid circuit board 2b. The fourth rigid circuit board 2c has a structure identical to that of the second rigid circuit board 2a.

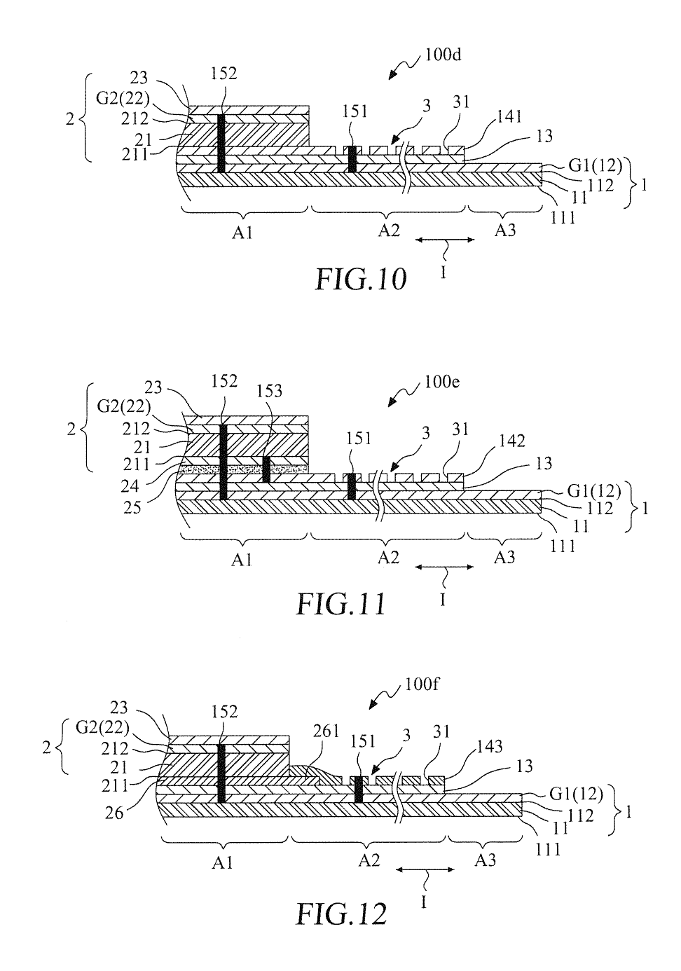

FIG. 10 is a cross-sectional view showing a fifth embodiment according to the present invention. A rigid-flexible circuit board 100d according to the instant embodiment has a structure that is an expanded structure formed by modifying the embodiment illustrated in FIG. 4. In the instant embodiment, besides being positioned on the extension section A2, the first shielding layer 141 further extends from the extension section A2 toward the stacking section A1 to be located between the first rigid-board substrate 21 of the first rigid circuit board 2 and the first flexible-board insulation layer 13 of the flexible circuit board 1.

Referring to FIG. 11, which is a cross-sectional view showing a sixth embodiment according to the present invention, a rigid-flexible circuit board 100e according to the instant embodiment comprises a first shielding layer 142 extends from an extension section A2 toward the stacking section A1 to reach in between the first rigid-board substrate 21 of the first rigid circuit board 2 and the first flexible-board insulation layer 13 of the flexible circuit board 1 and a rigid circuit board grounding section 24 is formed on the lower surface 211 of the first rigid-board substrate 21 of the first rigid circuit board 2. The rigid circuit board grounding section 24 is bonded by a bonding layer 25 to a surface of the first shielding layer 142 of the flexible circuit board 1 to correspond to the stacking section A1. The rigid circuit board grounding section 24 can be a conductive layer formed completely on the lower surface 211 of the first rigid-board substrate 21 or a localized conductive area.

The first shielding layer 142 is electrically connected through a first via hole 151 to a first flexible-board grounding line G1. First rigid-board grounding lines G2 are connected through a second via hole 152 to the first flexible-board grounding line G1 of the flexible circuit board 1. The rigid circuit board grounding section 24 and the first shielding layer 142 are electrically connected through at least one fifth via hole 153 to each other.

Referring to FIG. 12, which is a cross-sectional view showing a seventh embodiment according to the present invention, a rigid-flexible circuit board 100f according to the instant embodiment comprises a first rigid circuit board 5 that has a first rigid-board substrate 21 having a lower surface 211 on which an extended grounding section 26 is formed. The extended grounding section 26 is stacked on a top surface of a first flexible-board insulation layer 13 of a flexible circuit board 1 and corresponds to a stacking section A1. Further, the extended grounding section 26 comprises an end that extends beyond an end of the first rigid-board substrate 21 that faces the extension section A2 to form an extended section 261. In a preferred embodiment of the present invention, the extended grounding section 26 extends beyond the first rigid-board substrate 21 by a length between 1-10 mm. The length of the extension of the extended section 261 can be adjusted according to length of the extension section A2 of the flexible circuit board 1.

According to the present invention, a first shielding layer 143 is formed on a surface of the first flexible-board insulation layer 13 of the flexible circuit board 1 and corresponds to the extension section A2 and has at least a portion covering a surface of the extended section 261 of the extended grounding section 26 so that electrical connection is established between the first shielding layer 143 and the extended grounding section 26.

The first shielding layer 143 can be formed on the surface of the first flexible-board insulation layer 13 and the surface of the extended section 261 through for example printing and screen printing of a conductive substance, such as copper paste and silver paste. The first shielding layer 143 can be alternatively mounted on the surface of the first flexible-board insulation layer 13 and the surface of the extended section 261 by laminating or bonding a conductive foil, such as a copper foil, a silver foil, and an aluminum foil.

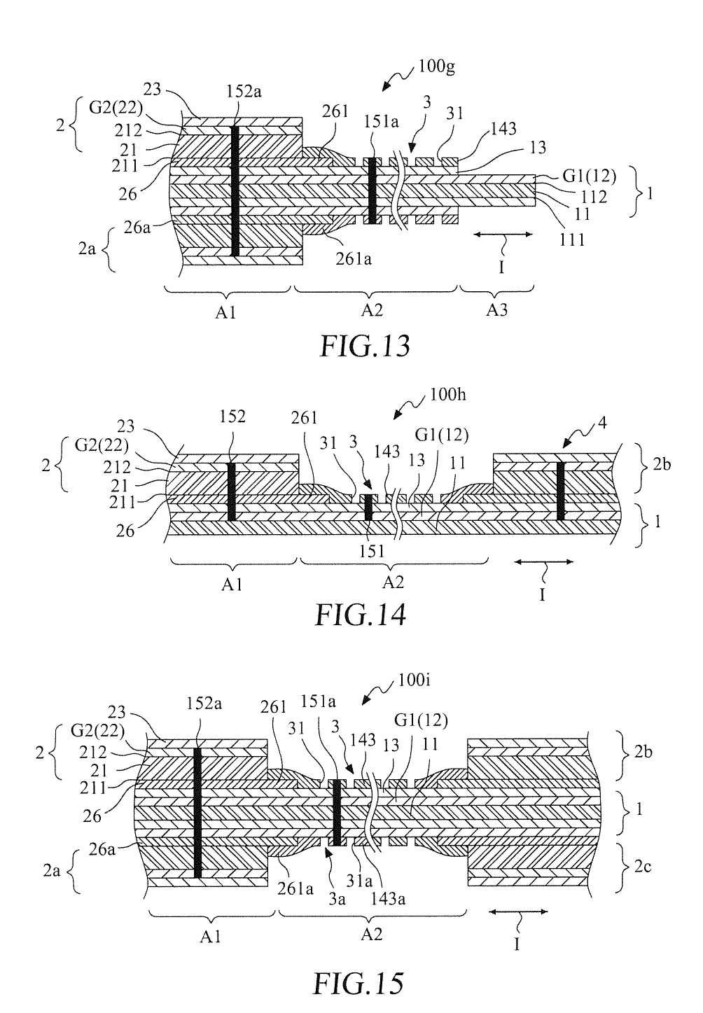

Similar to the modification made on the first embodiment, the embodiment shown in FIG. 12 can realize the present invention with a double-sided board. As shown in FIG. 13, a rigid-flexible circuit board 100g according to an eighth embodiment of the present invention comprises a structure that is an expanded structure formed by modifying the embodiment of FIG. 12 and comprising a flexible circuit board 1 comprising a flexible-board substrate 11 having an upper surface 112 on which first flexible-board differential mode signal lines 12, a first flexible-board insulation layer 13, a first shielding layer 143, a third via holes 151a, a first flexible-board grounding line G1, a first impedance control structure 3, openings 31, a first rigid-board substrate 21, first rigid-board differential mode signal lines 22, a first rigid-board grounding line G2, a first rigid-board insulation layer 23, and a fourth via hole 152a are similarly arranged.

The flexible circuit board 1 is further provided with a structure on a lower surface 111 of the flexible-board substrate 11 of the flexible circuit board 1 to correspond to that of the upper surface 112 and a second rigid circuit board 2a corresponding to the first rigid circuit board 2. Arranged between the second rigid circuit board 2a and the flexible-board substrate 11 is a structure including an extended grounding section 26a and an extended section 261a that correspond respectively to the extended grounding section 26 and the extended section 261.

The embodiment of FIG. 12 is shown to have an end of the flexible circuit board (namely, the exposed conduction section of the flexible circuit board) function as a golden-finger inserting structure and the other end coupled to the first rigid circuit board. Alternatively, one end of the flexible circuit board can be coupled to the first rigid circuit board, while the other end is coupled to another rigid circuit board to provide a left-right symmetric arrangement.

Referring to FIG. 14, which is a cross-sectional view showing a ninth embodiment according to the present invention, a rigid-flexible circuit board 100h according to the instant embodiment is an expanded structure formed by modifying the embodiment shown in FIG. 12 and the difference is that the flexible circuit board 1 is coupled to a third rigid circuit board 2b at a right end thereof that is opposite to the first rigid circuit board 2. The third rigid circuit board 2b has a structure identical to that of the first rigid circuit board 2. A first shielding layer 143 located between the first rigid circuit board 2 and the third rigid circuit board 2b forms a first impedance control structure 3 functioning for impedance control for the first flexible-board differential mode signal lines 12 of the flexible circuit board 1.

FIG. 15 is a cross-sectional view showing a tenth embodiment according to the present invention. The instant embodiment provides a rigid-flexible circuit board 100i that is an expanded structure formed by modifying the embodiment illustrated in FIG. 14 and comprises, in structure, a first rigid circuit board 2 mounted to the upper surface of the flexible circuit board 1 to correspond to the stacking section A1 and a second rigid circuit board 2a mounted to the lower surface. A third rigid circuit board 2b is mounted to the upper surface of the flexible circuit board 1 at a location of right end that is opposite to the first rigid circuit board 2 and a fourth rigid circuit board 2c is mounted to the lower surface to correspond to the third rigid circuit board 2b. The fourth rigid circuit board 2c has a structure identical to that of the second rigid circuit board 2a. A first shielding layer 143 located between the first rigid circuit board 2 and the third rigid circuit board 2b forms a first impedance control structure 3 functioning for impedance control for the first flexible-board differential mode signal lines 12 of the flexible circuit board 1. A second shielding layer 143a located between the second rigid circuit board 2a and the fourth rigid circuit board 2c forms a second impedance control structure 3a functioning for impedance control for the second flexible-board differential mode signal lines 12a of the flexible circuit board 1.

As to options of materials, the flexible-board substrate of the flexible circuit board can be made of one of PET (Polyester) or PI (Polyimide), which is flexible and is the form of a single layer or multiple layers, and the rigid circuit board substrate of the rigid circuit board can be made of one of glass fiber substrate, PI, ceramics, and aluminum board that is a single layer or multiple layers.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A circuit board with an impedance control structure, comprising:
at least one flexible circuit board, which defines a stacking section and an extension section, the extension section extending from an end of the stacking section, the flexible circuit board comprising:
a flexible-board substrate, which extends in an extension direction and comprises an upper surface and a lower surface;
a plurality of first flexible-board differential mode signal lines, which is formed on the upper surface of the flexible-board substrate and extends in the extension direction from the stacking section to the extension section;
at least one first flexible-board grounding line, which is formed on the upper surface of the flexible-board substrate and extends in the extension direction; and
a first flexible-board insulation layer, which is formed on the upper surface of the flexible-board substrate and covers the first flexible-board differential mode signal lines and the first flexible-board grounding line; and
at least one first rigid circuit board, comprising:
a first rigid-board substrate, which comprises an upper surface and a lower surface, the lower surface corresponding to and stacked on the stacking section of the flexible circuit board;
a plurality of first rigid-board differential mode signal lines, which is formed on the upper surface of the first rigid-board substrate and extends in the extension direction;
a first shielding layer, which is formed on the first flexible-board insulation layer of the flexible circuit board and corresponds to the extension section of the flexible circuit board, the first shielding layer being connected through at least one first via hole to the first flexible-board grounding line; and
a first impedance control structure, which is formed on the first shielding layer and corresponds to the first flexible-board differential mode signal lines of the flexible circuit board, whereby the first impedance control structure controls impedance of the first flexible-board differential mode signal lines.

2. The circuit board as claimed in claim 1, wherein:
the lower surface of the first rigid-board substrate of the first rigid circuit board comprises an extended grounding section formed thereon, the extended grounding section extending beyond an end of the first rigid-board substrate that faces the extension section to form an extended section; and
the first shielding layer has at least one portion adjacent the extended section to cover and electrically connect with the extended section.

3. The circuit board as claimed in claim 2, wherein the extended section has a length extending beyond the first rigid-board substrate, which is between 1-10 mm.

4. The circuit board as claimed in claim 1, wherein the first shielding layer extends from the extension section to reach in between the first flexible-board insulation layer and the first rigid-board substrate of the first rigid circuit board to correspond to the stacking section.

5. The circuit board as claimed in claim 4, wherein the lower surface of the first rigid-board substrate comprises a rigid circuit board grounding section formed thereon, the rigid circuit board grounding section being bonded by a bonding layer to a surface of the first shielding layer that corresponds to the stacking section, the rigid circuit board grounding section and the first shielding layer being electrically connected to each other by at least one fifth via hole.

6. The circuit board as claimed in claim 1, wherein the upper surface of the first rigid-board substrate comprises at least one first rigid-board grounding line formed thereon, the first rigid-board grounding line being electrically connected by at least one second via hole to the first flexible-board grounding line.

7. The circuit board as claimed in claim 1, wherein the first shielding layer is formed by printing one of copper paste and silver paste on the first flexible-board insulation layer.

8. The circuit board as claimed in claim 1, wherein the first shielding layer comprises one of a copper foil, a sliver foil, and an aluminum foil laminated on or bonded to the first flexible-board insulation layer.

9. The circuit board as claimed in claim 1, wherein the extension section has an end opposite to the stacking section and an exposed conduction section extends from the end in such a way that the exposed conduction section is not covered by the first flexible-board insulation layer.

10. The circuit board as claimed in claim 1, wherein the flexible circuit board comprises a plurality of slit lines that is formed by slitting in the extension direction, whereby the extension section forms a plurality of cluster lines.

11. The circuit board as claimed in claim 10, wherein the cluster lines are bundled by a bundling member.

12. The circuit board as claimed in claim 11, wherein the bundling member is made of an insulating material.

13. The circuit board as claimed in claim 11, wherein the bundling member comprises a wrapping layer that is made of a non-shielding material and a shielding layer formed on an outer circumferential surface of the wrapping layer.

14. The circuit board as claimed in claim 1, wherein the first impedance control structure comprises a plurality of openings formed in the first shielding layer of the flexible circuit board.

15. The circuit board as claimed in claim 1, wherein the first rigid-board substrate is made of a material of one of glass fiber substrate, polyimide, ceramics, and aluminum board.

16. The circuit board as claimed in claim 1, wherein the lower surface of the flexible-board substrate is further provided with:
a plurality of second flexible-board differential mode signal lines, which is formed on the lower surface of the flexible-board substrate to extend in the extension direction from the stacking section to the extension section;
at least one second flexible-board grounding line, which is formed on the lower surface of the flexible-board substrate to extend in the extension direction;
a second flexible-board insulation layer, which is formed on the lower surface of the flexible-board substrate and covers the second flexible-board differential mode signal lines and the second flexible-board grounding line;
a second shielding layer, which is formed below the second flexible-board insulation layer and corresponds to the extension section of the flexible circuit board, the second shielding layer being electrically connected by at least one third via hole to the second flexible-board grounding line, the first flexible-board grounding line, and the first shielding layer; and
a second impedance control structure, which is formed on the second shielding layer and corresponds to the second flexible-board differential mode signal lines, whereby the second impedance control structure controls impedance of the second flexible-board differential mode signal lines.

17. The circuit board as claimed in claim 16, wherein the lower surface of the second flexible-board insulation layer is further provided with at least one second rigid circuit board, the second rigid circuit board comprising:
a second rigid-board substrate, which comprises an upper surface and a lower surface, the upper surface being stacked on the lower surface of the second flexible-board insulation layer and corresponding to the stacking section;
a plurality of second rigid-board differential mode signal lines, which is formed on the lower surface of the second rigid-board substrate to extend in the extension direction; and
at least one second rigid-board grounding line, which is formed on the lower surface of the second rigid-board substrate to extend in the extension direction, the second rigid-board grounding line being electrically connected by at least one fourth via hole to a first rigid-board grounding line formed on the upper surface of the first rigid-board substrate.
